(19) United States
(12) Patent Application Publication
(10) Pub. No.: US 2006/0281244 A1
(43) Pub. Date: Dec. 14, 2006

(54) Nonvolatile semiconductor memory device and method of manufacturing the same

(76) Inventors: Masayuki Ichige, Yokohama-shi (JP); Fumitaka Arai, Yokohama-shi (JP); Atsuhiro Sato, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/447,941

(22) Filed: Jun. 7, 2006

(30) Foreign Application Priority Data
Jun. 8, 2005 (JP) 2005-168588

(51) Int. Cl. H01L 21/8238; H01L 29/94

(52) U.S. Cl. 438/211; 257/296

(57) ABSTRACT

A semiconductor memory device includes a semiconductor substrate. Two diffusion layers are separately arranged along a first direction on the surface of the semiconductor substrate and include impurities. Two element separation layers are separately arranged along a second direction in a surface of the semiconductor substrate and define an element region. A first insulating layer is disposed on the substrate. A first conductive layer is disposed on the first insulating layer between the two diffusion layers and between the two element separation layers. A second conductive layer is disposed on the first conductive layer and is smaller than the first conductive layer in the first direction and the second direction. A second insulating layer is disposed on the second conductive layer. A third conductive layer is disposed on the second insulating layer.

### CROSS-REFERENCE TO RELATED APPLICATIONS

This application is based upon and claims the benefit of priority from prior Japanese Patent Application No. 2005-168588, filed Jun. 8, 2005, the entire contents of which are incorporated herein by reference.

### BACKGROUND OF THE INVENTION

1. Field of the Invention

The present invention relates to a nonvolatile semiconductor memory device, more particularly to a memory cell structure suitable for high density and high integration, and a method of manufacturing the structure.

2. Description of the Related Art

A flash memory is well known as a nonvolatile semiconductor memory device which is capable of electrically rewriting data and which is suitable for high density and high capacity. To realize higher capacity, shrinking a design rule is kept facilitated by using fine process apparatus capable of fine process on a memory cell, and a device structure is reduced in accordance with a proportional reduction rule.

In a currently widely used NAND-type flash memory, a floating gate is disposed on a substrate via a tunnel insulating film, and electrons are injected or extracted to or from a floating gate by use of the Fowler-Nordheim (FN) tunnel phenomenon. It is therefore difficult to reduce a film thickness of the gate insulating film below a certain thickness.

Moreover, a coupling ratio, which represents a capacity ratio between an inter-electrode insulating film disposed between the floating gate and a control gate formed above the floating gate and the tunnel insulating film, needs to be over a certain value. Because a smaller device has a larger parasitic capacity, the inter-electrode insulating film needs to have large capacity. However, it is difficult to reduce the thickness of the inter-electrode insulating film, which is one of methods for a high capacity of the inter-electrode insulating film. This means that the thickness of the tunnel insulating film or the inter-electrode insulating film cannot be reduced in accordance with the reduction of the design rule of the memory cell.

In order to maintain a constant coupling ratio, the floating gate needs to have a long rectangular shape to realize a larger area for miniaturization due to an influence of the parasitic capacity. This method increases a facing area of the floating gate between the adjacent two cells. This structure increases the capacity between adjacent two floating gate in adjacent cells with a help of reduced distance between adjacent cells owing to the miniaturization. This results in higher interfering effect between the cells, which is the fluctuation of a threshold value of a memory cell transistor owing to charges accumulated in the adjacent memory cells. Therefore, the threshold values of the memory cells apparently fluctuate. This problem is becoming remarkable.

That is, the interfering effect between the cells increases, when the device is miniaturized. The effect has a larger influence on a multi-valued memory cell in which a range of the allowed threshold value needs to be controlled to be small.

To solve the problem, there is proposed a method to form a floating gate of a flash memory with two layers (see, e.g., Jpn. Pat. Appln. KOKAI Publication No. 2004-22819). In particular, this method includes: forming the first floating-gate layer of polycrystalline silicon before forming an element separation region; and selectively depositing a polycrystalline silicon layer as the second floating-gate layer on only the first floating-gate layer in a self-aligning manner.

When the second polycrystalline silicon layer is grown on the element separation insulating film in a lateral direction with this proposed method, a width of the floating gate is set larger than that of the tunnel insulating film. This increases the area of the inter-electrode insulating film, and the coupling ratio can eventually be increased. However, the proposed method is not suitable for the miniaturization of the cell because the adjacent second floating gates are brought closer to each other and it is more difficult to realize the surrounding structure owing to miniaturization.

On the other hand, there is proposed a method in which a gate width of a second silicon layer of the floating gate which includes two layers is smaller than that of a first silicon layer by use of a conventional chemical vapor deposition (CVD) process (see, e.g., Jpn. Pat. Appln. KOKAI Publication No. 2001-284556).

However, when a buried trench deepens, a burying performance of the CVD process has a restriction. Since the second silicon layer formed by the CVD process has a small gate width and the trench cannot be deep owing to the burying restriction, this method cannot realize the large area of the inter-electrode insulating film to increase the capacity. Therefore, the coupling ratio is also small.

### BRIEF SUMMARY OF THE INVENTION

According to an aspect of the present invention, there is provided a semiconductor memory device comprising: a semiconductor substrate; two diffusion layers separately arranged along a first direction on the surface of the semiconductor substrate and including impurities; two element separation layers separately arranged along a second direction in a surface of the semiconductor substrate and defining an element region; a first insulating layer disposed on the substrate; a first conductive layer disposed on the first insulating layer between the two diffusion layers and between the two element separation layers; a second conductive layer disposed on the first conductive layer and being smaller than the first conductive layer in the first direction and the second direction; a second insulating layer disposed on the second conductive layer; and a third conductive layer disposed on the second insulating layer.

According to an aspect of the present invention, there is provided a method of manufacturing a semiconductor device, comprising: forming a first insulating layer on a semiconductor substrate and a first conductive layer on the first insulating layer; forming two element separation layers separated along a first direction, the two element separation layers extending through the first insulating layer and the first conductive layer to reach the semiconductor substrate and defining an element region; forming a second conductive layer on the first conductive layer, the second conductive layer being smaller than the first conductive layer in both the first direction and a second direction which connects two diffusion layers formed in a subsequent step and including impurities; forming a second insulating layer on the second conductive layer; forming a third conductive layer on the second insulating layer; and forming the two diffusion layers along the second direction in a surface of the semiconductor substrate so that the two diffusion layers sandwich the first conductive layer.

### BRIEF DESCRIPTION OF THE SEVERAL VIEWS OF THE DRAWING

FIG. 1 is a plan view of a nonvolatile semiconductor memory device according to Embodiment 1;

FIGS. 2 and 3 are diagrams showing a sectional structure of the nonvolatile semiconductor memory device according to Embodiment 1;

FIGS. 4, 5, 6, 7, 8A, 8B, 9, 10, 11 and 12 are sectional views showing steps of manufacturing the nonvolatile semiconductor memory device according to Embodiment 1;

FIGS. 13A and 13B are sectional views showing a step of manufacturing a nonvolatile semiconductor memory device according to Embodiment 2;

FIG. 14 is a sectional view showing a step of manufacturing a nonvolatile semiconductor memory device according to Embodiment 3;

FIG. 15 is a diagram showing a sectional structure of a nonvolatile semiconductor memory device according to Embodiment 4;

FIGS. 16A and 16B are sectional views showing a step of manufacturing the nonvolatile semiconductor memory device according to Embodiment 4;

FIGS. 17A, 17B and 17C are diagrams showing a sectional structure of the nonvolatile semiconductor memory device according to Embodiment 4;

FIGS. 18 and 19 are diagrams showing a sectional structure of a nonvolatile semiconductor memory device according to Embodiment 5; and

FIGS. 20 and 21 are diagrams showing a sectional structure of a nonvolatile semiconductor memory device according to Embodiment 6.

### DETAILED DESCRIPTION OF THE INVENTION

Embodiments of the present invention will be described hereinafter.

### Embodiment 1

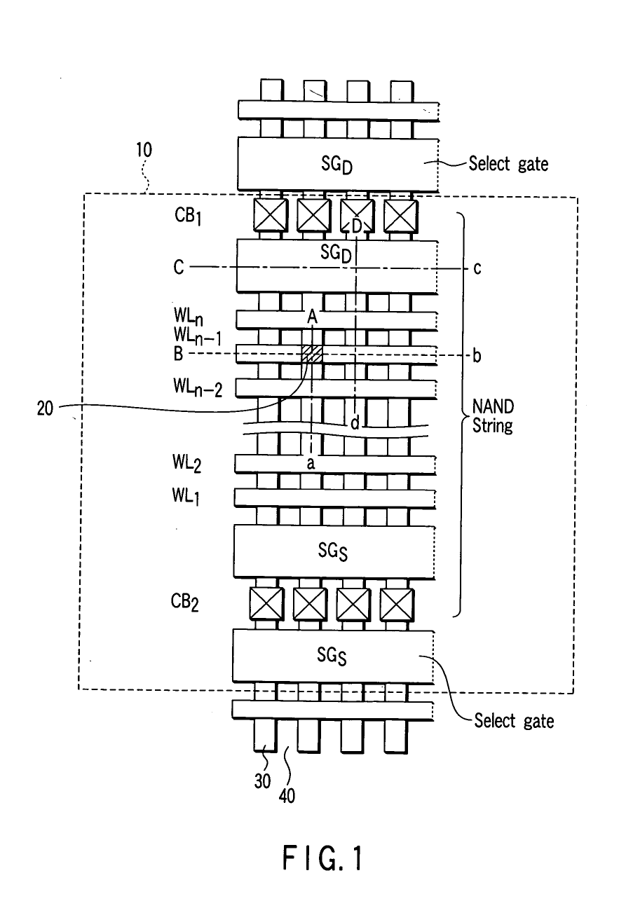

Embodiment 1 of the present invention will be described with reference to FIGS. 1 to 12.

FIG. 1 is a plan view showing a constitution carried out in an NAND cell type electrically erasable programmable read only memory (EEPROM) in the present embodiment. Among EEPROMs, an NAND cell type EEPROM is known which can realize high integration. Multiple memory cells are connected in series in the NAND cell type EEPROM. In FIG. 1, reference numeral 10 denotes one block of memory cell array.

In this EEPROM, each memory cell 20 has a channel, a source diffusion layer and a drain diffusion layer formed in a semiconductor substrate. As shown in FIG. 1, among the memory cells, adjacent cells are connected in series so that the source and drain diffusion layers are shared to form an NAND string. The drain diffusion layer on one end of the NAND string is connected to a bit line BL via a select gate SG_{D}, and the source diffusion layer on the other end is connected to a common source line SL via a select gate SG_{S}. Control gates CG of the respective memory cells are integrated to form a word line WL extending in a row direction. Such memory cells are arranged into a matrix to constitute an EEPROM.

The word lines WL and select gates SG_{D}, SG_{S} are selectively driven based on address signals during writing, erasing and reading of data. This address signal is supplied from a row decoder (not shown). A predetermined voltage is supplied to the bit line BL from a sense amplifier and a writing and reading circuit (not shown).

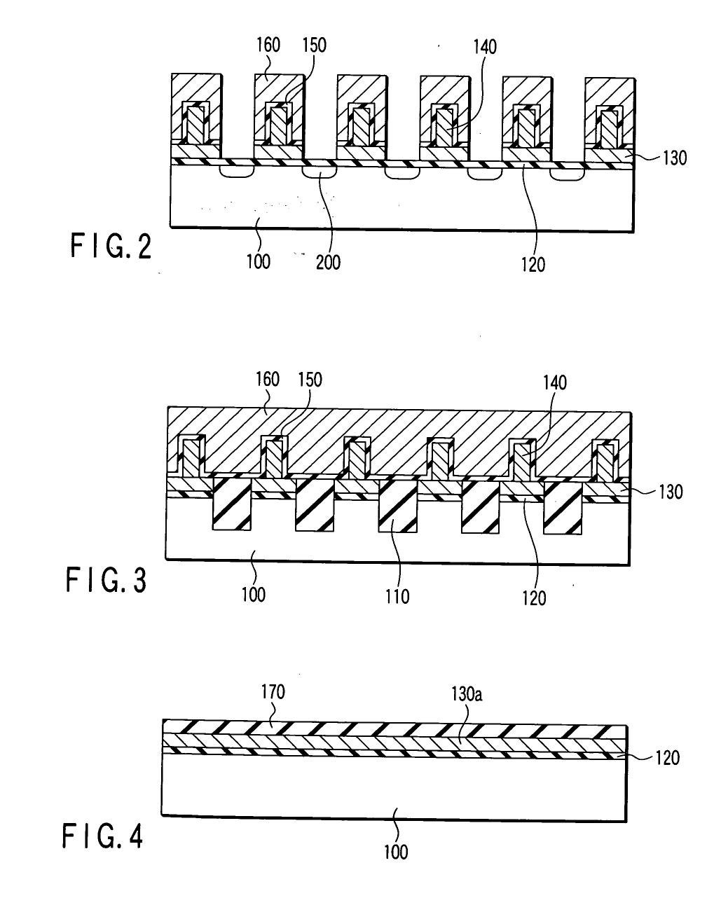

FIG. 2 is a sectional view cut along the A-a line of FIG. 1, that is, a view along a bit line direction. FIG. 3 is a sectional view cut along the B-b line of FIG. 1, that is, a view along a word line direction.

In the sectional structures of the memory cell in the bit line direction of FIG. 2 and the word line direction or FIG. 3, trenches for separating elements are formed in a substrate 100 made of p-type silicon. In the trenches, an element separation insulating material such as a silicon oxide film is buried to form an element separation layer 110.

On the whole surface of a channel region of the substrate provided with such element separation layer 110, a tunnel insulating film 120 is formed as a thin insulating film which allows a tunnel current to flow. The tunnel insulating film 120 is made of a silicon oxide film having a thickness of, for example, 10 nm or less. A first conductive layer 130 is formed on the tunnel insulating film 120. The first conductive layer 130 is made of polycrystalline silicon obtained by partly crystallizing polycrystalline silicon or amorphous silicon to which, for example, phosphor has been added with a high concentration. As shown in FIG. 3, a side end of this first conductive layer 130 is in the same position as that of an end of the element separation layer 110. Note that polycrystalline silicon obtained by partly crystallizing polycrystalline silicon or amorphous silicon will hereinafter be referred to generically as polysilicon.

A second conductive layer 140 is formed on the first conductive layer 130 so that the second conductive layer is physically and electrically connected to the first conductive layer. A laminate structure of the first conductive layer 130 and the second conductive layer 140 constitutes a floating gate FG which is an electric charge accumulating layer.

In both of the bit line direction (FIG. 2) and the word line direction (FIG. 3), a width of the second conductive layer 140 in each memory cell is smaller than that of the first conductive layer 130. In the boundary between the first conductive layer 130 and the second conductive layer 140, a width of the bottom of the second conductive layer 140 is smaller than that of the top of the first conductive layer 130, therefore a step is formed.

The top and a periphery of the second conductive layer 140 are coated with an inter-electrode insulating film 150.

The inter-electrode insulating film 150 is made of, for example, a silicon nitrogen oxide film. The inter-electrode insulating film is not limited to the silicon nitrogen oxide film. For example, some layers of silicon oxide films and silicon nitride films may be laminated, or the film may be formed by partly nitriding the silicon oxide film. A part of the first conductive layer or polysilicon forming the first conductive layer may be nitrided to form an insulating film. Alternatively, as a so-called high dielectric film, it may be, for example, an aluminum oxide film, a hafnium oxide film, a laminated film including these films, a mixed film of them, these oxide films which is partly nitrided or the like. Alternatively, the silicon oxynitride film may be combined with the high dielectric film.

On the inter-electrode insulating film 150, there is formed a control gate CG constituted of a third conductive layer 160 made of, for example, polysilicon. On the top of the first conductive layer 130, there is a region where no second conductive layer 140 is formed, and the inter-electrode insulating film 150 is formed in this region.

The first and third conductive layers 130, 160 in the bit line direction (FIG. 2) are processed in a self-aligning manner so that side faces of the layers are aligned with the surface of the substrate in a substantially perpendicular direction. An n-type diffusion layer 200 is formed between the gates in the bit line direction.

The word line direction (FIG. 3) is different from the bit line direction (FIG. 2) in that the control gate CG formed of the third conductive layer 160 is shared between the cells connected in series.

Next, there will be described a method of manufacturing a nonvolatile semiconductor memory device in Embodiment 1 with reference to FIGS. 4 to 14.

First, the tunnel insulating film 120 is formed on the semiconductor substrate 100. On the tunnel insulating film 120, a first polysilicon layer 130a to which impurities have been added is deposited as the first conductive layer 130 by use of a CVD process or the like. A mask layer 170 of photo resist is deposited as a mask material on the first polysilicon layer 130a (see FIG. 4).

Next, the mask layer 170, the first polysilicon layer 130a, the tunnel insulating film 120 and the substrate 100 are etched so that side ends of the layers are aligned with one another, thereby forming trenches.

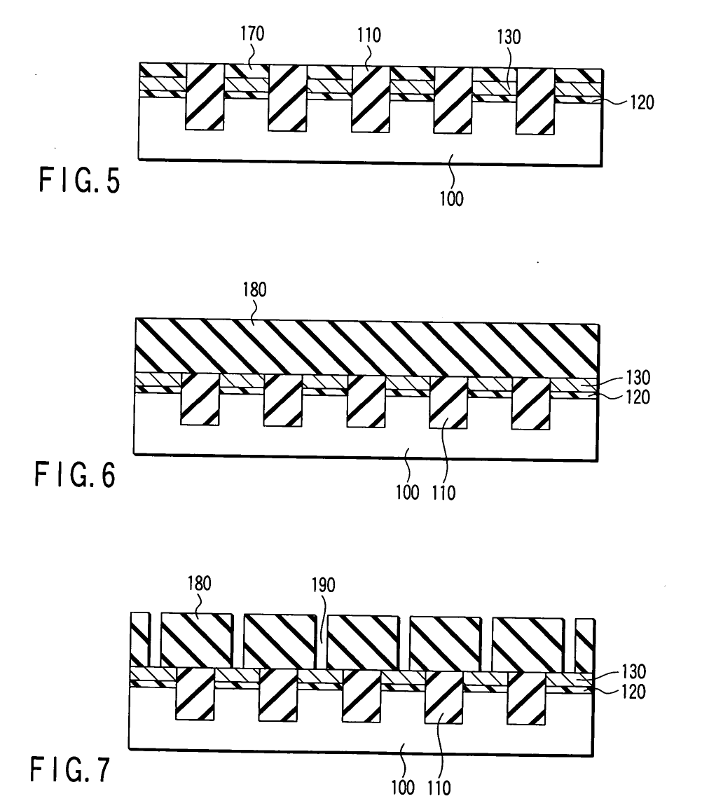

Side walls of the trenches and the surface of a side wall of the first polysilicon layer are oxidized by performing, for example, an oxidization or surface reforming. Next, the element separation layer 110 is deposited on the whole surface and flattened by etching-back such as dry etching or surface polishing such as chemical mechanical polishing (CMP) until the top of the mask layer 170 is exposed (see FIG. 5).

After peeling the mask layer 170 to expose the top of the first polysilicon layer (first conductive layer 130), a sacrifice layer 180 formed of, for example, a silicon oxide film is deposited in a thickness of, for example, about 300 nm (see FIG. 6).

The sacrifice layer 180 is coated with the resist, a mask is processed using a conventional lithography process, and openings 190 are formed in the sacrifice layer 180 on the first polysilicon layer (see FIG. 7).

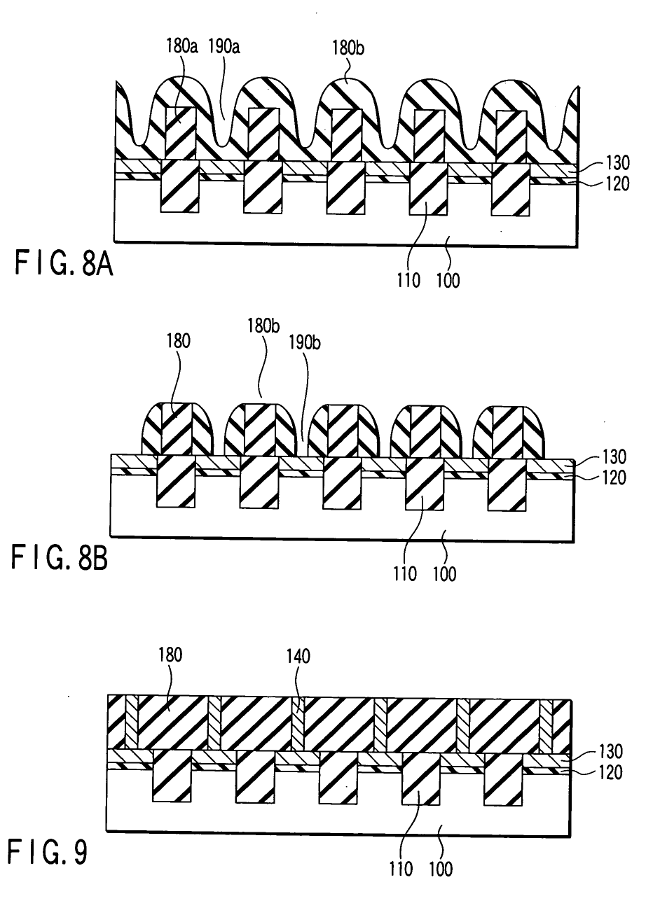

During this process, that widths of each opening 190 in the bit line direction and the word line direction are controlled to be smaller than those of the first polysilicon layer of each memory cell in the bit line direction and the word line direction, respectively. Description is now given in detail on one example of a manufacturing method for forming openings 190 that are thinner than the first polysilicon layer like this with reference to FIGS. 8A and 8B.

As shown in FIG. 8A, first a first sacrifice layer 180a is deposited, and openings 190a are formed using a conventional photolithography process. At this time, the width of the opening 190a may be equal to or larger than that of the first polysilicon layer in the bit line direction and the word line direction. A second sacrifice layer 180b formed of, for example, a silicon oxide film is formed on the whole surface including the openings 190a by use of the CVD process or the like. The forming of the film is stopped so that the second sacrifice layer 180b does not completely fill in the openings 190a but is deposited on a side wall and a bottom of each opening 190 only. A configuration shown in FIG. 8B is obtained.

Opening 190b is formed in the bottom of the opening 190a of the second sacrifice layer 180b by use of an etching process such as a chemical dry etching (CDE) process or a reactive ion etching (RIE) process so that a part of the first conductive layer 130 is exposed (see FIG. 8B). When the first sacrifice layer 180a and the second sacrifice layer 180b are used, opening 190 can be formed so that the widths of the pore in the bit line direction and the word line direction are smaller than those of the first polysilicon layer in the directions.

Here, the shape of the side wall of opening 190b (the opening 190) does not have to be linear as shown in FIG. 7. The opening 190 may be tapered so that the width of the opening increases upwards, or inversely tapered. Alternatively, the side wall of the opening 190 may have an uneven surface.

Next, in opening 190, there is formed a second polysilicon layer forming the second conductive layer 140 by selective growth using the first polysilicon layer as a core. The second polysilicon layer formed by the selective growth contains a high concentration of phosphor as a dopant.

Description is now given on a method of selectively growing the second polysilicon layer doped with phosphor.

The substrate having the openings 190 in the surface thereof as shown in FIG. 7 is conveyed into a low-pressure CVD (LPCVD) furnace, and dichlorosilane (DCS), hydrogen chloride (HCl) or phosphine (PH₃) is supplied as a material gas to the surface of the substrate. An atmosphere gas may contain hydrogen (H₂), nitrogen (N₂) or the like. During the film forming, a substrate temperature was set at about 600° C. to about 900° C., a pressure was set to about 5 Torr to 50 Torr, and the concentration of phosphor in the formed polysilicon film was 1×10²⁰ cm⁻³ or more. As a result, polysilicon doped with phosphor grew at a rate of about 2 nm/min to about 10 nm/min. Control on a height of the opening 190 formed beforehand can control a height of the second polysilicon layer in opening 190 which is also controlled by film forming time. The sacrifice layer 180 for forming the openings 190 is deposited to be thick, and the height of each opening 190 is set beforehand to 300 nm or more, therefore the thickness of the formed second polysilicon layer can be controlled into 300 nm or more.

A film forming condition which allows a selective growth can prevent a formation of second polysilicon layer on an area but for the opening 190 such as the top of the sacrifice layer 180 (see FIG. 9).

Here, even when opening 190 is provided with taper or surface unevenness, the second polysilicon layer can selectively be grown into such shape as to fill in the opening 190.

The opening with the tapered shape or the surface irregularities may be preferable because it increases the surface area of the second conductive layer 140.

When the second polysilicon layer selectively grows thicker than the sacrifice layer 180 for forming the openings 190, the surface of the second polysilicon layer can thereafter be flattened using the CMP process or the like. This flattening process is preferable because the height of the second conductive layer 140 can be uniformed among different memory cells.

The second polysilicon layer formed by such selective growth constitutes the second conductive layer 140 which is electrically and physically connected to the first conductive layer.

Here, the top of the first polysilicon layer may be treated with a solution and purified to thereby form a remarkably thin oxide film on the first polysilicon layer. This thin oxide film may result in sandwiched between the first polysilicon layer and the second polysilicon layer after the second polysilicon layer selectively grows. However, since this oxide film is remarkably thin, it provides no problem in electric conduction and keeps an equal potential between the first polysilicon layer and the second polysilicon layer.

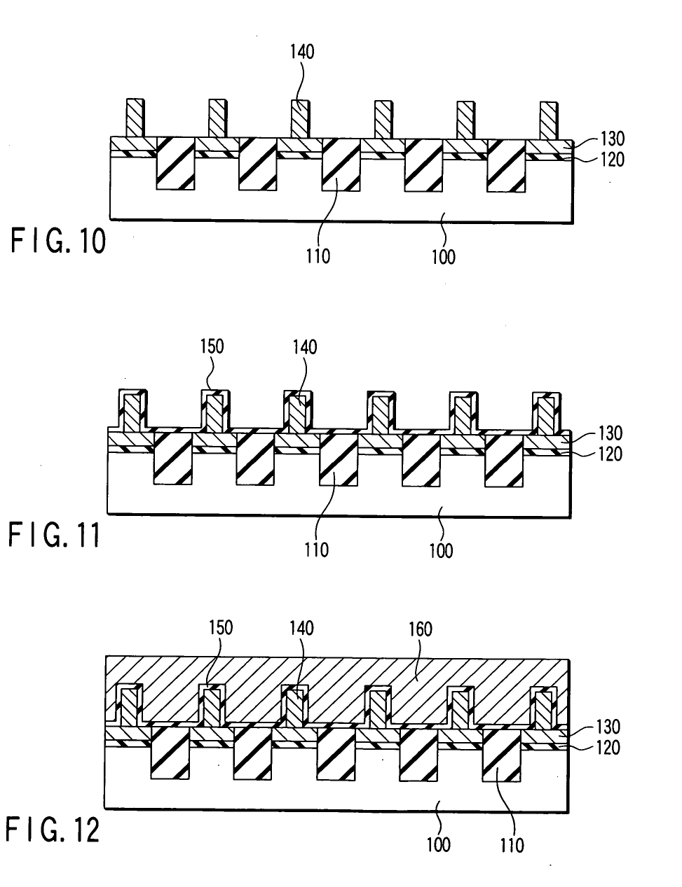

Next, the sacrifice film 180 used in forming the openings 190 is peeled by a wet etching process using a solution containing hydrofluoric acid or the like or a dry etching process such as the CDE process (see FIG. 10). When the first sacrifice layer 180a and the second sacrifice layer 180b are used in forming the openings 190 as described above, the first and second sacrifice films 180a, 180b are similarly peeled.

Next inter-electrode insulating film 150 is deposited on the whole surface of the second polysilicon layer including the top and the periphery thereof (see FIG. 11). The inter-electrode insulating film 150 may be a laminate structure formed of a silicon nitride film and a silicon oxide film. Alternatively, it may be a deposited silicon oxide film nitrided to thereby form a silicon oxynitride film, or a so-called high dielectric film (e.g., aluminum oxide, hafnium oxide, oxynitride of them, nitride, a mixture of them, a laminated film or the like). Alternatively, they may be combined to form a laminate structure or a mixed-phase film.

Next, the third conductive layer 160 formed of a third polysilicon layer containing a high concentration of phosphor as a dopant is deposited on the whole surface by use of the CVD process or the like (see FIG. 12). The third conductive layer 160 forms the control gate CG. At this time, a low-resistance film (not shown) made of silicide or the like may be deposited on the third conductive layer 160. The gates are processed in the bit line direction to separate the memory cells and ions are injected to form the diffusion layer 200 on the substrate 100, and thereby a transistor is formed to complete a memory cell structure (see FIGS. 2 and 3).

Such memory cell in Embodiment 1 has the following characteristics. In the memory cell of Embodiment 1, the inter-electrode insulating film 150 is covered with the third conductive layer 160. This structure brings an electric shield effect to shield any cell from a parasitic capacity between adjacent cells to prevent the capacity from influencing the cell. In consequence, an interfering effect between the adjacent cells can remarkably be reduced. When the thickness of the first conductive layer 130 is controlled to be small as compared with the height of the second conductive layer 140, the interfering effect between adjacent cells can be suppressed.

Moreover, in the manufacturing method of Embodiment 1, it is possible to control the height of the second conductive layer 140 by the selective growth, and it is possible to form the second conductive layer in a high-aspect-ratio opening which a conventional CVD process faces difficulty to fill.

Furthermore, control on the height of the second conductive layer can control the area of the floating gate to increase the coupling ratio. Still further, that the second conductive layer 140 is narrower than the first conductive layer 130 can improve fill-in characteristics of the inter-electrode insulating film 150 and the third conductive layer 160 on it.

### Embodiment 2

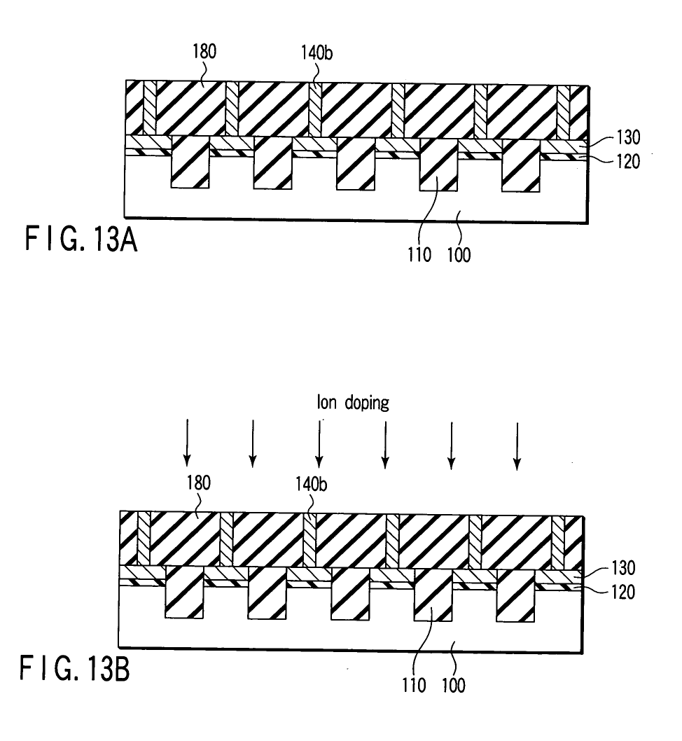

Embodiment 2 of the present invention will be described with reference to FIG. 13.

Embodiment 2 is different from Embodiment 1 in that a polysilicon layer with no impurity intentionally introduced is formed by selective growth instead of the second polysilicon layer to which phosphor has been applied in Embodiment 1, and thereafter impurities are added to the polysilicon layer by an ion doping.

Since a structure of Embodiment 2 is equivalent to that of Embodiment 1, the structure is not described anew here. Since a manufacturing method of Embodiment 2 is equivalent to that of Embodiment 1 but for a method of forming the second conductive layer 140 in Embodiment 1, the same description is omitted here.

The embodiment will be described with reference to FIG. 13A. In the same manner as in Embodiment 1, a substrate having openings 190 is conveyed into an LPCVD furnace, and a dichlorosilane (DCS) gas and a hydrogen chloride (HCl) gas are supplied as a material gas to the surface of the substrate. A substrate temperature was set at about 700° C. to about 800° C., and a pressure was set to about 5 Torr to about 20 Torr. As a result, a second polysilicon layer grew at a rate of about 3 nm/min to about 20 nm/min, and a dopant concentration in the film was 1×10¹⁹ cm⁻³ or less. At this time, the second polysilicon layer was not deposited on a silicon insulating film as an element separation layer 110 or a sacrifice layer 180, and polysilicon selectively grew in the openings 190 only.

Next, as shown in FIG. 13B, phosphor ions are injected into the second polysilicon layer by an ion doping.

Thereafter, the surface of the second conductive layer 140 is flattened using a process such as a CMP process, and a shape of the second conductive layer 140 is uniformed.

An activating thermal treatment may additionally be performed to activate the ions which are doped into the second conductive layer 140. Alternatively, in a subsequent step, the activating may be performed simultaneously with a thermal treatment.

A configuration of the memory cell of Embodiment 2 has an effect equivalent to that of Embodiment 1. Furthermore, the manufacturing method of Embodiment 2 can increase the film forming rate as compared with a film forming method in which impurities are added simultaneously with the film forming. As a result, productivity is improved.

The present invention is not limited to the above constitution, and can variously be modified. For example, in Embodiment 2, the phosphor ions are injected during doping, but arsenic may be used. Alternatively, boron or the like may be used to form a p-type floating gate.

### Embodiment 3

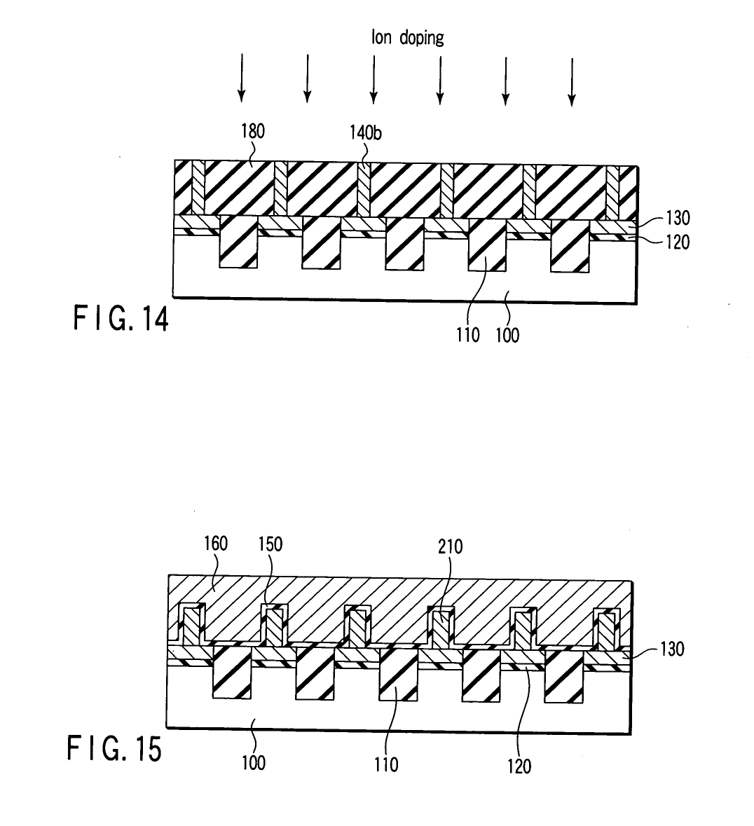

Embodiment 3 of the present invention will be described with reference to FIG. 14.

Embodiment 3 is equivalent to Embodiment 2 in that a second polysilicon layer with no dopant intentionally introduced is selectively grown when forming a second conductive layer 140. In Embodiment 2, the dopant is introduced using ion injection, but Embodiment 3 is different in that a gas doping is used in which impurities are added from a gas phase.

Embodiment 3 is equivalent to Embodiment 1 in a structure and a manufacturing method but for formation method of the second conductive layer 140. Therefore, this respect is not described anew herein.

Moreover, since Embodiment 3 is equivalent to Embodiment 2 in a process of forming polysilicon with no impurity added in each opening 190 by selective growth, the process is not described anew here.

The embodiment will be described with reference to FIG. 14. A substrate 100 in which the second polysilicon layer has selectively grown in the only opening 190 is conveyed into a vacuum device, and the substrate is thermally treated in a phosphine (PH₃) gas or an AsH₃ gas diluted with, for example, an inactive gas or hydrogen. This doping may be performed continuously with the selective growth of polysilicon. By this thermal treatment, phosphor or arsenic is introduced as a dopant.

Thereafter, the surface of the second conductive film 140 is flattened using a process such as a CMP process, and a shape of the second conductive film 140 is uniformed.

A configuration of the memory cell of Embodiment 3 has an effect equivalent to that of Embodiment 1. Furthermore, the manufacturing method of Embodiment 3 can increase the film forming rate as compared with a film forming method in which impurities are added simultaneously with the film forming. As a result, productivity is improved.

The present invention is not limited to the above constitution, and can variously be modified. For example, in Embodiment 3, phosphor ions are injected during doping, but a gas containing boron or the like may be used to form a p-type floating gate.

### Embodiment 4

Embodiment 4 is different from Embodiments 1 to 3 in that silicon germanium (SiGe) is used in at least a part of a second conductive layer 140, whereas a polysilicon layer is used in the second conductive layer 140 in Embodiments 1 to 3.

Since silicon germanium is used, selective growth having the same selectivity as that of polysilicon is possible, a film forming rate is higher than that of polysilicon, and thereby productivity is improved. Moreover, silicon germanium has a high resistance to a high-temperature treatment as compared with polysilicon, and is especially effective in a nonvolatile semiconductor memory device having a high thermal budget and a method of manufacturing the device.

Since the whole structure of the nonvolatile semiconductor memory device of Embodiment 4 is equivalent to that shown in FIG. 1 in Embodiment 1, the structure is not described anew here. A sectional structure of the nonvolatile semiconductor memory device of Embodiment 4 is shown in FIG. 15. Embodiment 4 is different from Embodiment 1 in that silicon germanium is used in the second conductive layer 140. As shown in FIG. 15, the second conductive layer is formed of a silicon germanium layer 210.

Next, a manufacturing method of Embodiment 4 will be described. Since Embodiment 4 is equivalent to Embodiment 1 but for the manufacturing method, this respect is not described anew here.

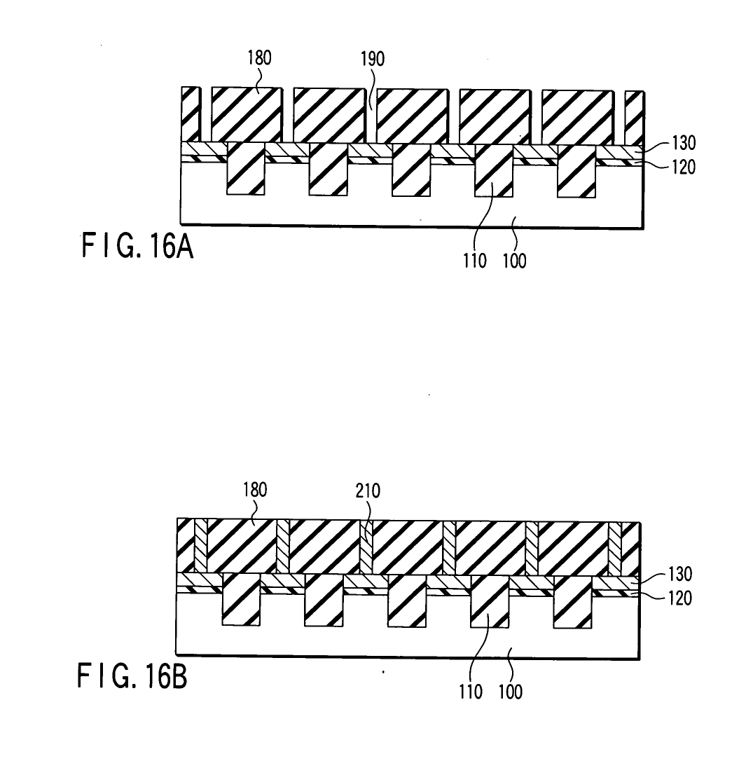

The embodiment will be described with reference to FIGS. 16A, 16B. A substrate 100 formed in the same manner as in FIG. 7 and having openings 190 is conveyed into an LPCVD furnace, and a dichlorosilane (DCS), germane (GeH₄) and phosphine (PH₃) gas is supplied as a material gas to the surface of the substrate (see FIG. 16A). A substrate temperature was set at about 700° C. to 800° C., and a pressure was set to about 5 Torr to about 20 Torr. As a result, silicon germanium grew at a rate of about 3 nm/min to about 30 nm/min. A germanium concentration in silicon germanium can be set to about 10 atomic % to about 80 atomic % by controlling a gas flow rate during the film formation. At this time, silicon germanium is not deposited on a silicon insulating film as an element separation layer 110, and silicon germanium can selectively be grown in the openings 190 only (see FIG. 16B).

Thereafter, the surface of the second conductive layer 140 made of silicon germanium is flattened using a process such as a CMP process, and a shape of the second conductive layer 140 is uniformed.

Next, an inter-electrode insulating film is formed on the whole surface including the surface of the second conductive layer 140. Since the subsequent steps are equivalent to those of Embodiment 1, they are not described anew here.

A configuration of the memory cell of Embodiment 4 has an effect equivalent to that of Embodiment 1. Furthermore, the manufacturing method of Embodiment 4 can increase the film forming rate as compared with the film forming methods of Embodiments 1 to 3. As a result, productivity is improved. Moreover, silicon germanium has a smaller thermal capacity during film formation than silicon, and is especially effective when the thermal capacity is desired to be reduced in order to improve device performances and the like in a process of manufacturing a semiconductor device.

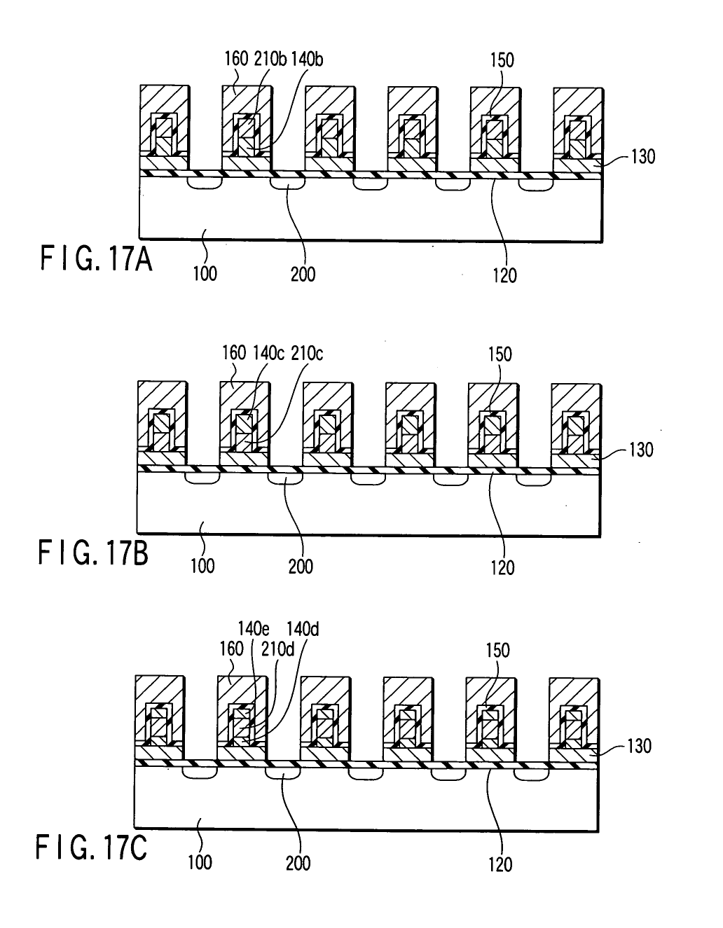

The present invention is not limited to the above constitution, and can variously be modified. For example, as shown in FIG. 17A, it is possible to form on the polysilicon layer a second conductive layer constituted of a polysilicon layer 140b and a silicon germanium layer 210b formed by selective growth on a first conductive layer 130. As shown in FIG. 17B, it is possible to form on the first conductive layer 130a second conductive layer constituted of a silicon germanium layer 210c and a polysilicon layer 140c formed on the silicon germanium layer by selective growth. Alternatively, as shown in FIG. 17C, it is possible to form on the first conductive layer 130a second conductive layer constituted of a three-layer structure of a polysilicon layer 140d, a silicon germanium layer 210d and a polysilicon layer 140e by selective growth.

Since the polysilicon layer is deposited on silicon germanium, the inter-electrode insulating film does not directly come into contact with silicon germanium. This can alleviate disadvantage such as flowing of the surface of the inter-electrode insulating film during film formation, degradation on a film quality of the inter-electrode insulating film, or accumulation of electric charges in the interface. A structure of the polysilicon layer deposited under silicon germanium can inhibit the flowing of the first conductive layer which might occur when silicon germanium is selectively grown directly on the first conductive layer.

### Embodiment 5

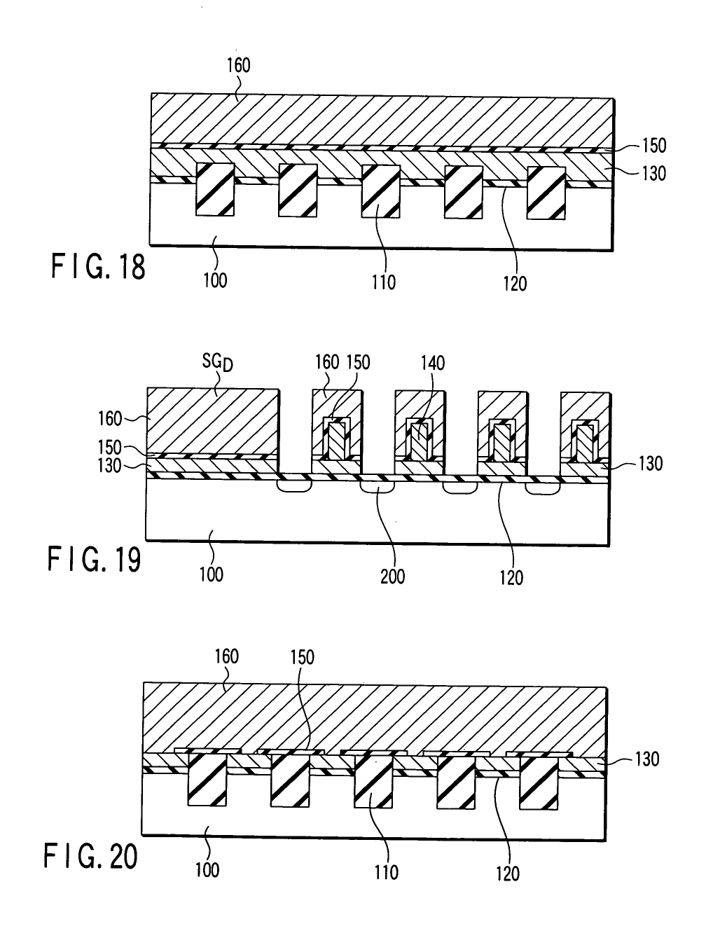

Embodiment 5 of the present invention will be described with reference to FIGS. 18 and 19.

In Embodiments 1 to 4, a drain-side select gate SG_{D} and a source-side select gate SG_{S} have a second conductive layer 140 which is selectively grown on a first conductive layer 130 as in a memory cell 20. Embodiment 5 is different from the other embodiments in that the drain-side select gate SG_{D} does not have the second conductive layer 140.

Since a plan view of a nonvolatile semiconductor memory device of Embodiment 5 is equivalent to FIG. 1 of Embodiment 1, the plan view is not described anew here. Since a sectional structure of the memory cell of Embodiment 5 is equivalent to that shown in FIGS. 2 and 3 in Embodiment 1, the structure is not described anew here.

This embodiment will be described with reference to FIG. 18. FIG. 18 is a sectional view of a memory cell array cut along the line C-c of FIG. 1, that is, a sectional view of a drain-side select gate SG_{D} portion in a word line direction. FIG. 19 is a sectional view cut along the line D-d of FIG. 1, that is, a sectional view of the drain-side select gate SG_{D} portion in a bit line direction. The drain-side select gate SG_{D} is constituted of the first conductive layer 130 and a third conductive layer 150, and the second conductive layer 140 is not formed on the first conductive layer 130.

As described above, a floating gate similar to a memory cell can be formed in the select gate SG_{D}. In such structure, select gate SG_{D} may be subjected to a write to set a threshold value before the data is written into a memory cell portion.

Moreover, it is possible to realize a structure (not shown) in which the first conductive layer 130 comes into an electric contact with the third conductive layer 150 in an desired position of the select gate SG_{D} of the cell array.

Such structure can readily control the threshold value of the drain-side select gate SG_{D}, and the memory cell array can easily be miniaturized.

A section of a source-side select gate SG_{S} portion can also have a sectional structure equivalent to that of the drain-side select gate SG_{D}.

### Embodiment 6

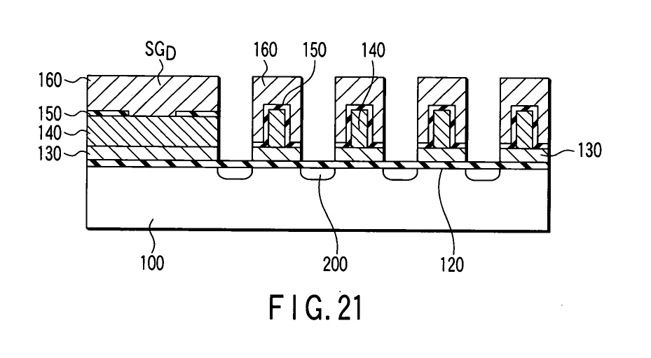

Embodiment 6 of the present invention will be described with reference to FIGS. 20 and 21.

In Embodiments 1 to 4, a drain-side select gate SG_{D} and a source-side select gate SG_{S} have a floating gate formed of the first and second conductive layers 130, 140 and a control gate formed of the third conductive layer 160 which is formed on the second conductive layer 140 via an inter-electrode insulating film 150. Embodiment 6 is different from the other embodiments in that the drain-side select gate SG_{D} and the source-side select gate SG_{S} have an opening in each inter-electrode insulating film 150 to short-circuit the first, second and third conductive layers 130, 140 and 160.

Since a plan view of a nonvolatile semiconductor memory device of Embodiment 6 is equivalent to FIG. 1 of Embodiment 1, the plan view is not described anew here. Since a sectional structure of the memory cell of Embodiment 6 is equivalent to that shown in FIGS. 2 and 3 in Embodiment 1, the structure is not described anew here.

The embodiment will be described with reference to FIG. 20. FIG. 20 is a sectional view of a memory cell array cut along the line C-c of FIG. 1, that is, a sectional view of a drain-side select gate SG_{D} portion in a word line direction. FIG. 21 is a sectional view cut along the line D-d of FIG. 1, that is, a sectional view of the drain-side select gate SG_{D} portion in a bit line direction. The drain-side select gate SG_{D} has the opening in the inter-electrode insulating film 150, and the first conductive layer 130, the second conductive layer 140 and the third conductive layer 160 are electrically connected to one another to be short-circuited. Such structure can realize an easy control on the threshold values of the drain-side select gate SG_{D} and the source-side select gate SG_{S} and easy miniaturization of the memory cell array.

A section of a source-side select gate SG_{S} portion can have a sectional structure equivalent to that of the drain-side select gate SG_{D} portion.

The present invention is not limited to the above constitution, and can variously be modified. For example, in Embodiments 1 to 6, polysilicon or silicon germanium is formed as the second conductive layer, but the second conductive layer may be constituted of a metal formed using a selective growth process, and embodiments of the material include tungsten and molybdenum. When the material having a smaller work function than that of polysilicon is selectively grown in the second conductive layer, a leak current from the inter-electrode insulating film can be suppressed. The structures and processes described in Embodiments 1 to 6 can appropriately be combined and carried out.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor memory device comprising:
a semiconductor substrate;
two diffusion layers separately arranged along a first direction on the surface of the semiconductor substrate and including impurities;
two element separation layers separately arranged along a second direction in a surface of the semiconductor substrate and defining an element region;
a first insulating layer disposed on the substrate;
a first conductive layer disposed on the first insulating layer between the two diffusion layers and between the two element separation layers;
a second conductive layer disposed on the first conductive layer and being smaller than the first conductive layer in the first direction and the second direction;
a second insulating layer disposed on the second conductive layer; and
a third conductive layer disposed on the second insulating layer.

2. The device according to claim 1, wherein the second insulating layer is disposed on a top of the first conductive layer, and on a side and a top of the second conductive layer.

3. The device according to claim 1, wherein the third conductive layer covers a top of the first conductive layer, and a side and a top of the second conductive layer via the second insulating layer.

4. The device according to claim 1, wherein a side of the first conductive layer in the second direction comes into contact with sides of the two element separation layers.

5. The device according to claim 1, wherein the first conductive layer includes a polysilicon made conductive, silicon germanium made conductive or a structure comprising at least stacked two layers of polysilicon made conductive and silicon germanium made conductive.

6. The device according to claim 1, further comprising:
a fourth conductive layer disposed on the first insulating layer, separated from the first conductive layer, and constituted of the same layer as the first conductive layer;
a third insulating layer disposed on the fourth conductive layer, separated from the second insulating layer, and constituted of the same layer as the second insulating layer; and
a fifth conductive layer disposed on the third insulating layer, separated from the third conductive layer, and constituted of the same layer as the third conductive layer.

7. The device according to claim 1, further comprising:
a fourth conductive layer disposed on the first insulating layer, separated from the first conductive layer, and constituted of the same layer as the first conductive layer;
a fifth conductive layer disposed on the fourth conductive layer, separated from the second conductive layer, and constituted of the same layer as the second conductive layer;
a third insulating layer disposed on the fifth conductive layer, separated from the second insulating layer, constituted of the same layer as the second insulating layer, and having an opening; and
a sixth conductive layer disposed on the third insulating layer, separated from the third conductive layer, constituted of the same layer as the third conductive layer, and connected to the fifth conductive layer in the opening.

8. A method of manufacturing a semiconductor device, comprising:
forming a first insulating layer on a semiconductor substrate and a first conductive layer on the first insulating layer;
forming two element separation layers separated along a first direction, the two element separation layers extending through the first insulating layer and the first conductive layer to reach the semiconductor substrate and defining an element region;
forming a second conductive layer on the first conductive layer, the second conductive layer being smaller than the first conductive layer in both the first direction and a second direction which connects two diffusion layers formed in a subsequent step and including impurities;
forming a second insulating layer on the second conductive layer;
forming a third conductive layer on the second insulating layer; and
forming the two diffusion layers along the second direction in a surface of the semiconductor substrate so that the two diffusion layers sandwich the first conductive layer.

9. The method according to claim 8, wherein forming the second conductive layer includes:
forming a first layer on the first conductive layer, the first layer being smaller than the first conductive layer in the first direction and the second direction and having a hole reaching the first conductive layer from its top;
burying the second conductive layer in the hole; and
removing the first layer.

10. The method according to claim 8, wherein forming the second insulating layer includes:
forming the second insulating layer on a top of the first conductive layer, and on a side and a top of the second conductive layer.

11. The method according to claim 10, wherein forming the third conductive layer includes:
covering the top of the first conductive layer, and the side and the top of the second conductive layer via the second insulating layer.

12. The method according to claim 8, wherein forming the second conductive layer includes:
growing a semiconductor layer to which conductivity has been given with the first conductive layer used as a core.

13. The method according to claim 12, wherein forming the semiconductor layer to which the conductivity has been given includes:
growing the semiconductor layer while injecting impurities which give the conductivity to the semiconductor layer.

14. The method according to claim 12, wherein forming the semiconductor layer to which the conductivity has been given includes:
growing the semiconductor layer; and
introducing impurities which give the conductivity to the semiconductor layer into the semiconductor layer.

15. The method according to claim 14, wherein introducing the impurities includes:
injecting ions of the impurities into the semiconductor layer.

16. The method according to claim 14, wherein introducing the impurities includes:
injecting a gas including the impurities into the semiconductor layer.
